(19) United States
(12) Patent Application Publication
(10) Pub. No.: US 2013/0026528 A1
(43) Pub. Date: Jan. 31, 2013

(54) WATERPROOF TRANSPARENT LED SHIELD STRUCTURE

(71) Applicant: Shuei-Tian CAI, Taichung City (TW)

(72) Inventor: Shuei-Tian CAI, Taichung City (TW)

(73) Assignee: SAFETY TRAFFIC EQUIPMENT CO., LTD., Taichung City (TW)

(21) Appl. No.: 13/192,005

(22) Filed: Jul. 27, 2011

(51) Int. Cl. H01L 33/58

(52) U.S. Cl. 257/99; 257/E33.066

(57) ABSTRACT

A waterproof transparent LED shield structure has a singular LED component with a circuit board and an LED lighting component, with the circuit board connected with protruding electric pins. A hard transparent shield has a base board and a shield. The base board covers the front side of the circuit board, and is configured with a rim to rest against the edge of the circuit board. The shield has a circular side wall and a top end and encloses the LED lighting component. A soft waterproof covering body covers and is attached to the outside of the LED component and hard transparent shield. The soft waterproof covering has a seat part and a projecting part. The seat covers the circuit board, the connecting end of the electric pins and the base board and rim, and the protruding end of the electric pins extends out of the seat part.

### CROSS-REFERENCE TO RELATED U.S. APPLICATIONS

Not applicable.

### STATEMENT REGARDING FEDERALLY SPONSORED RESEARCH OR DEVELOPMENT

Not applicable.

### NAMES OF PARTIES TO A JOINT RESEARCH AGREEMENT

Not applicable.

### REFERENCE TO AN APPENDIX SUBMITTED ON COMPACT DISC

Not applicable.

### BACKGROUND OF THE INVENTION

1. Field of the Invention

The present invention relates generally to an LED-related component, and more particularly to an innovative waterproof transparent LED shield structure which can be combined with singular LED components.

2. Description of Related Art Including Information Disclosed Under 37 CFR 1.97 and 37 CFR 1.98

At present, as a replacement of traditional lights, LED is widely used in various products for illumination. Applications of LED can be seen in general lamps, projection lamps, traffic lights, traffic sign boards, advertising light boxes, automobile lamps, etc.

However, in spite of the advantages of LED in usage, there are still many technical problems in the application to be overcome or improved. To provide planar illumination, numerous LED lights are arranged in an array, and all the LED lights shall be connected to each other through electric wires or through a circuit board. However, at each connecting point, there are chances of water seepage or dampness to some extent due to the application environment of the product, resulting in risks of short circuit and damage. Hence, it has become an important technical issue to provide waterproof encapsulation for the circuit structure of LED products for safety and durability.

In the prior-art waterproof structure of LED products, the electric wires or the circuit board is entirely covered by waterproof glue. Such a waterproof structure can solve the problem, but due to the considerable use of glue, the production cost is high and production time is long. For some products, the high production cost and high pricing will not be easily accepted by the consumers. Secondly, in case of any partial damage of the LED structure, such a waterproof structure will be very difficult and inconvenient to repair. This is a disadvantage complained of by the consumers.

Thus, to overcome the aforementioned problems of the prior art, it would be an advancement if the art to provide an improved structure that can significantly improve the efficacy.

Therefore, the inventor has provided the present invention of practicability after deliberate design and evaluation based on years of experience in the production, development and design of related products.

### BRIEF SUMMARY OF THE INVENTION

The efficacy improvements of the present invention are as follows:

The “waterproof transparent LED shield structure” disclosed in the present invention mainly features an innovative and unique structure assembly of the singular LED component, hard transparent shield and soft waterproof covering body, so that the hard transparent shield can provide a hard protection shield for the circuit board and the LED lighting component of the singular LED component. Furthermore, a soft waterproof covering body is adopted to form an external waterproof structure. The soft waterproof covering body has a through hole for the shield top end to extend out and be exposed, so the illumination effect will not be affected. Hence, compared to the known techniques of “prior-art”, the overall structure of the present invention can provide better waterproof and protection effect for the singular LED structure, and can effectively improve the installation quality and product durability.

The present invention can generate the following new efficacies:

The configuration of electric pins extending straightly to the outside of the circuit board of the singular LED component offers the possibility of a flat design of the LED lighting component and shield (see FIG. 11), so that the overall LED module can be flat and thin, and can be more easily attached through adhesive, and in case of inserting, it can also reduce the occupying space of the overall LED structure.

Although the invention has been explained in relation to its preferred embodiment, it is to be understood that many other possible modifications and variations can be made without departing from the spirit and scope of the invention as hereinafter claimed.

### BRIEF DESCRIPTION OF THE SEVERAL VIEWS OF THE DRAWINGS

FIG. 1 is an exploded perspective view of the components of a preferred embodiment of the present invention.

FIG. 2 is a perspective view of the assembled state of the components of a preferred embodiment of the present invention.

FIG. 3 is a sectional view of the assembled state of the components of a preferred embodiment of the present invention.

FIG. 4 is a sectional view of the disassembled state of the singular LED component and hard transparent shield of the present invention.

FIG. 5 is a schematic view of an embodiment illustration with the structure of the present invention fixed onto a board-shaped object through clasping.

FIG. 6 is a perspective view of the structure of the present invention fixed into aboard-shaped object (Note: the board-shaped object is partially sectioned).

FIG. 7 is a plan sectional view of the structure of the present invention fixed into a board-shaped object.

FIG. 8 is a schematic view of an embodiment illustration showing the rim of the present invention is in the shape of multiple spaced sheets.

FIG. 9 is a schematic view of another embodiment illustration of the structure of the present invention.

FIG. 10 is a schematic view of a further embodiment illustration of the structure of the present invention.

FIG. 11 is a schematic view of an embodiment illustration of the structure of the present invention fixed onto a board-shaped object through adhesive.

FIG. 12 is an Embodiment Illustration 1 showing variation of the shape of the structure of the present invention.

FIG. 13 is an Embodiment Illustration 2 showing variation of the shape of the structure of the present invention.

FIG. 14 is an Embodiment Illustration 3 showing variation of the shape of the structure of the present invention.

### DETAILED DESCRIPTION OF THE INVENTION

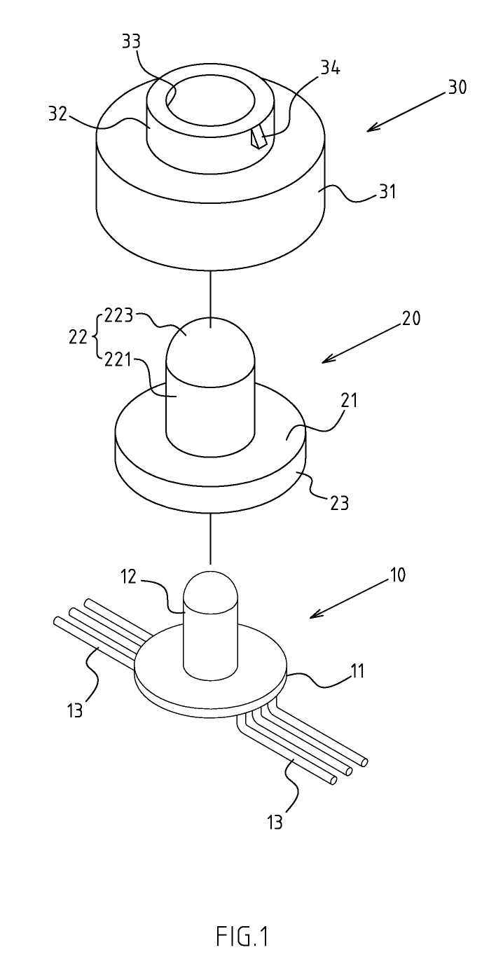

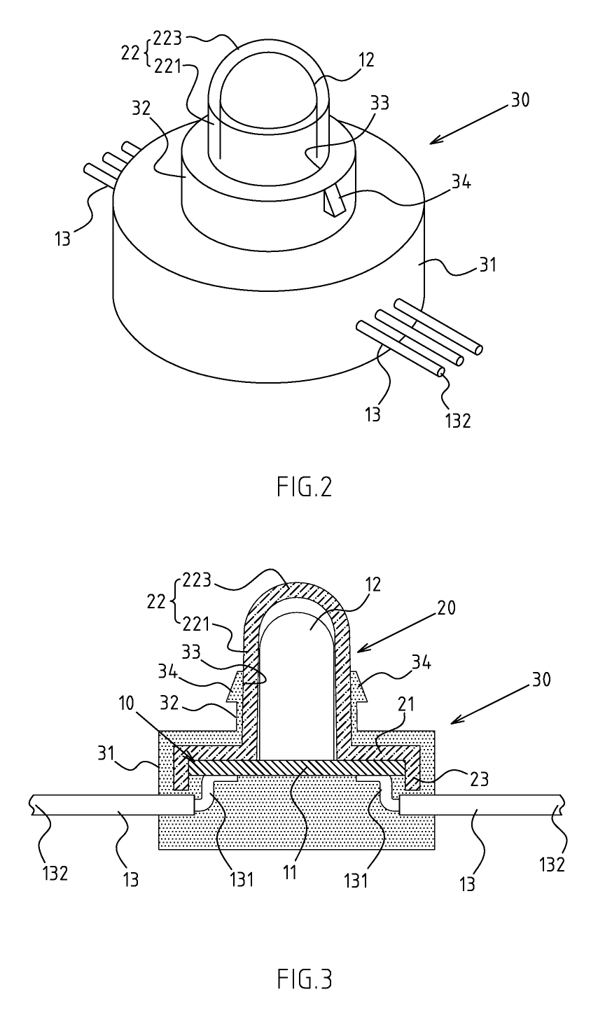

FIGS. 1, 2, 3, and 4 show a preferred embodiment of the improved waterproof transparent LED shield structure of the present invention. However, such an embodiment is for description purposes only and shall not restrict the claims of patent application.

Said waterproof transparent LED shield structure comprises a singular LED component 10, including a circuit board 11 and an LED lighting component 12 connected on the front surface of the circuit board 11, and also multiple protruding electric pins 13 connected on the back surface of the circuit board 11.

A hard transparent shield 20 which can be integrally formed of transparent acrylic material, and which is attached to the front surface of the circuit board 11 of the singular LED component 10. The hard transparent shield 20 comprises a base board 21 and an integral shield 22 protruding from the center of the base board 21, where the base board 21 is to cover the front side of the circuit board 11, and the base board 21 is configured with a rim 23 on the side edge, and the rim 23 can resist against the side of the circuit board 11 for limitation and stabilization. Or, there can also be a space between the rim 23 and the side of the circuit board 11. The shield 22 comprises a circular side wall 221 and a top end 223, the shield 22 is to enclose the LED lighting component 12, and the light beams from the LED lighting component can go through the shield 22.

A soft waterproof covering body 30 is made of soft flexible material (e.g. rubber or silicone) and directly formed (i.e. formed through mould projection), covering and attached to the outside of the singular LED component 10 and the hard transparent shield 20.

The soft waterproof covering body 30 comprises a seat part 31 and a projecting part 32 configured on the center of one side of the seat part 31. The seat part 31 is to cover the circuit board 11 of the singular LED component 10, the connecting end 131 of the electric pins 13, and the base board 21 and rim 23 of the hard transparent shield 20 (as shown in FIG. 3), and the protruding end 132 of the electric pins 13 extends out of the seat part 31. The projecting part 32 encloses the circular side wall 221 of the shield 22 of the hard transparent shield 20. The projecting part 32 has a through whole 33 on the end for the top end 223 of the shield 22 to extend outside and be exposed.

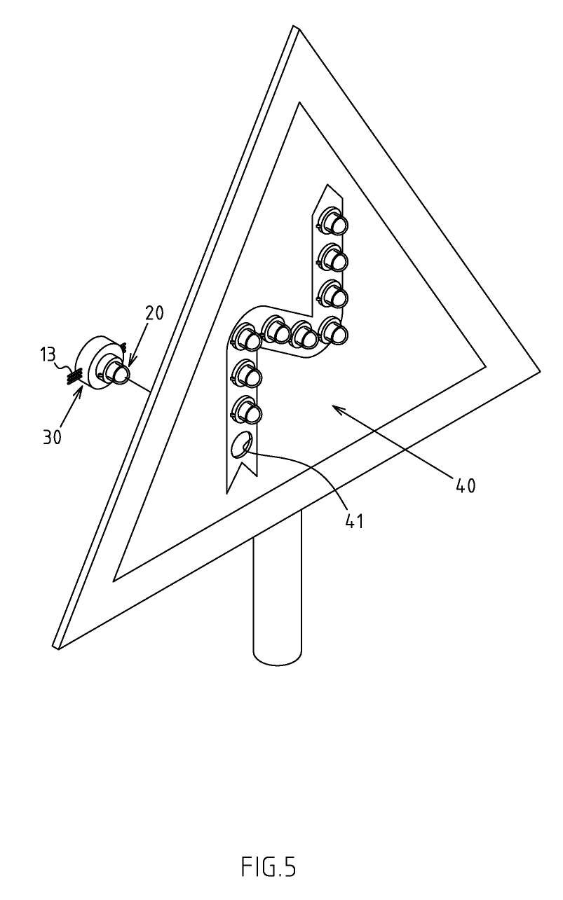

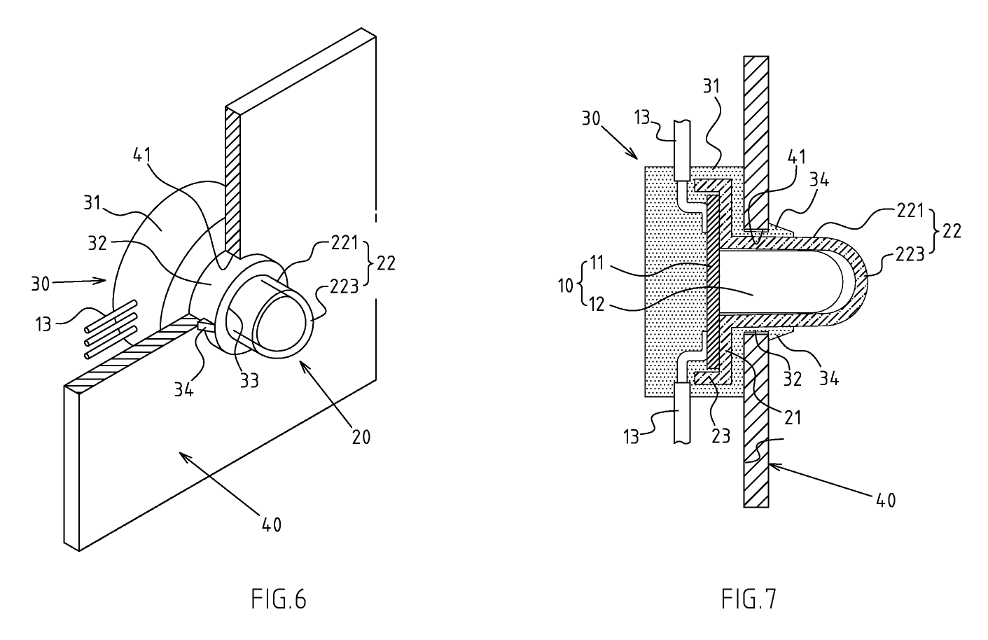

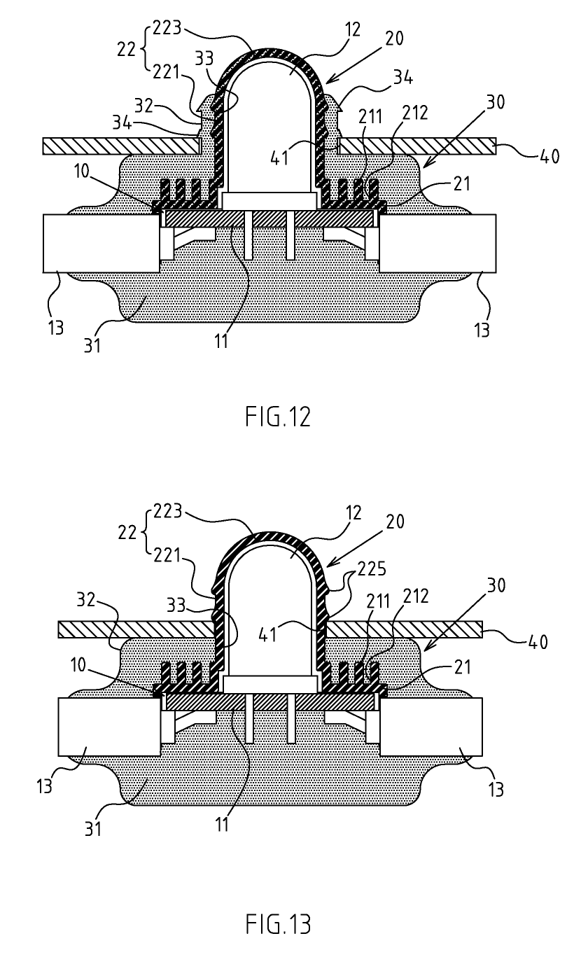

Referring to FIGS. 1, 2, and 3, the projecting part 32 of the soft waterproof covering body 30 can be further configured with a clip fixing pin 34. The shape of the clip fixing pin 34 can be in any form like spaced teeth or a ring-shaped flange. As shown in FIGS. 5, 6, and 7, through the clip fixing pin 34, the product can be fixed onto the preset through holes 41 of a board-shaped object 40 (can be a traffic sign board, advertising object, board-shaped decorative structure etc). Furthermore, as shown in FIG. 12, the clip fixing pin 34 can be configured as one stage or spaced multi-stages. In the configuration of spaced multi-stages, it can fit board-shaped objects 40 of different thickness.

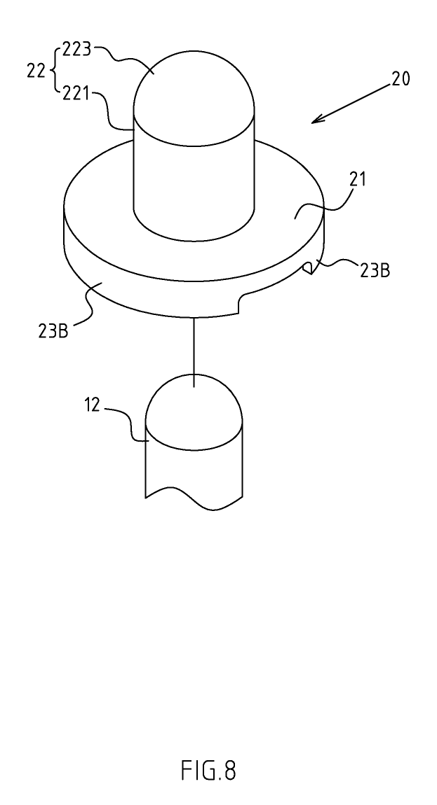

As shown in FIG. 1, the rim 23 configured on the side of the base board 21 of the hard transparent shield 20 can be a ring-shaped frame; or, as shown in FIG. 8, the rim 23B is in the shape of spaced multiple sheets.

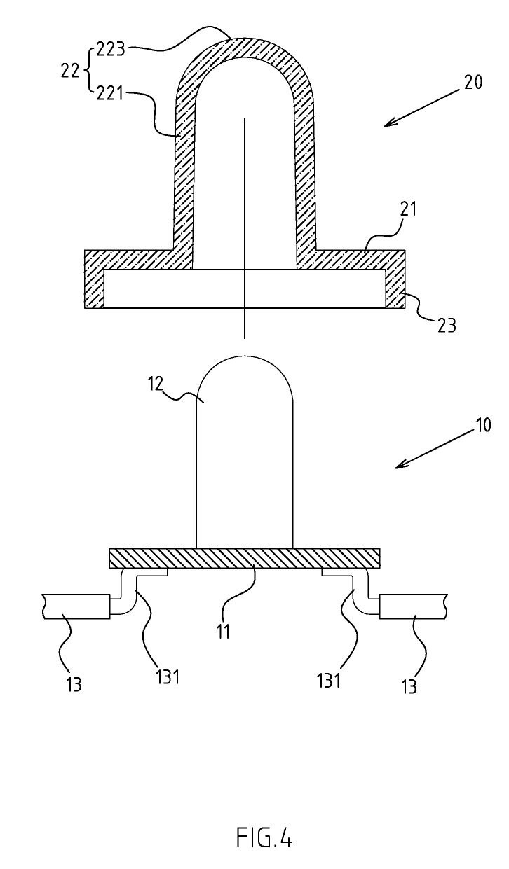

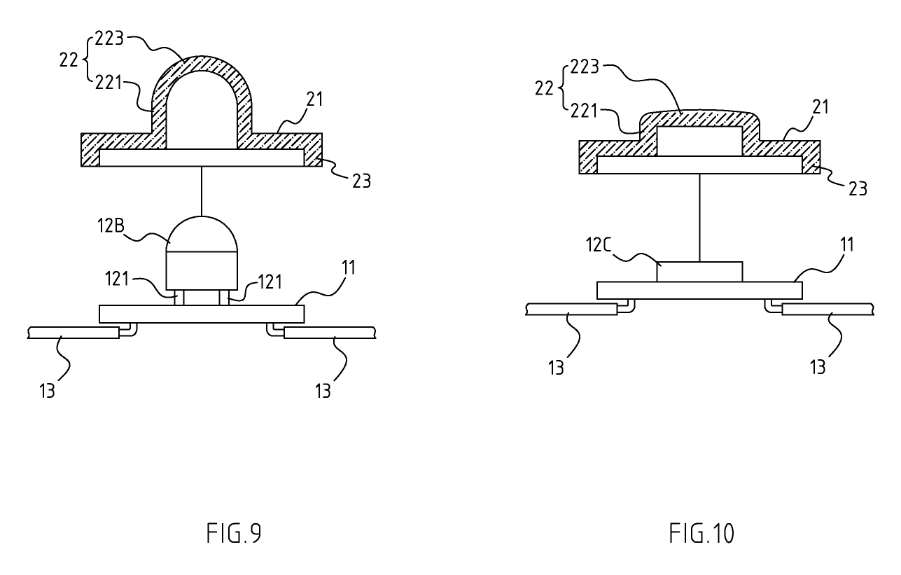

Furthermore, the LED lighting component 12 configured on the front side of the circuit board 11 of the singular LED component 10 can be in forms of multiple embodiments. For instance, the LED lighting component 12 shown in FIGS.1-3 is a high cylinder-shaped granule; the LED lighting component 12B shown in FIG. 9 is a low cylinder-shaped granule. The LED lighting component 12C shown in FIG. 10 is a flat rectangular granule. The LED lighting component 12 can directly resist against the circuit board 11 (as shown in FIGS. 4 and 10), or, as shown in FIG. 9, there is a space between the LED lighting component 12B and the circuit board 11 with configuration of the electric pins 121.

As shown in FIGS. 1-4, the electric pins 13 configured on the back side of the circuit board 11 of the singular LED component 10 can be folded like the letter “L”; or, as shown in FIG. 8-10, the electric pins 13B extend straightly to the outside of the circuit board 11. Such an embodiment can further reduce the height and make the product flat and thin.

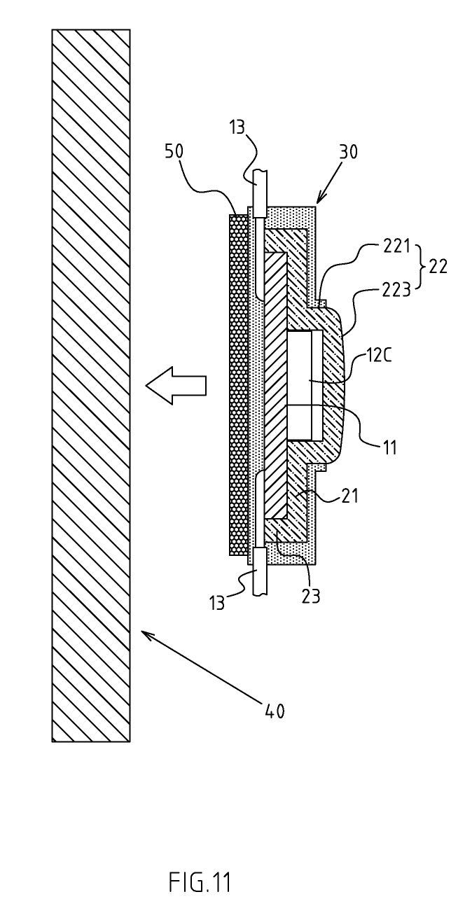

As shown in FIG. 11, the front or back sides of the seat part 31 of the soft waterproof covering body 30 can be adhered with double-sided adhesive 50, through which the product can be adhered onto the surface of a board-shaped object 40 (can be a traffic sign board, advertising object, board-shaped decorative structure etc).

As shown in FIGS. 12 and 13, the surface of the base board 21 of the hard transparent shield 20 can be further configured with multiple flanges 211, and slots 212 are formed between the flanges 211 for the soft waterproof covering body 30 to be inserted into, so as to enhance the fixing stability between the soft waterproof covering body 30 and the hard transparent shield 20.

As shown in FIG. 13, the circular side wall 221 of the shield 22 of the hard transparent shield 20 is further configured with clip fixing pin 225. The clip fixing pin 225 can be in either form of spaced teeth or a ring-shaped flange; through this, the product can be fixed onto the preset through holes 41 of a board-shaped object 40. Furthermore, the clip fixing pin 225 can be configured as one stage or spaced multi-stages; in the configuration of spaced multi-stages, it will fit board-shaped objects 40 of different thickness.

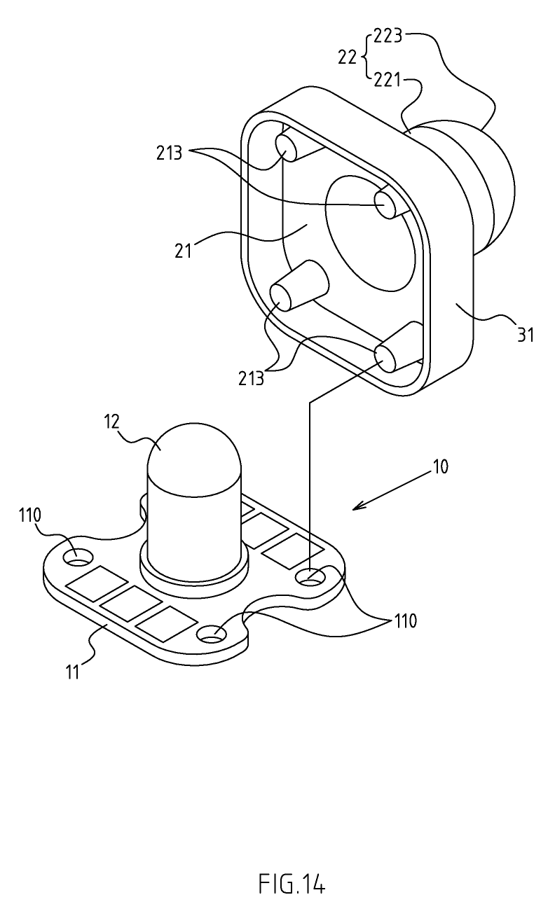

As shown in FIG. 14, the base board 21 of the hard transparent shield 20 is further configured with multiple inserting columns 213 extending to the direction of the circuit board 11, and the circuit board 11 is correspondingly configured with multiple fixing holes 110 for the inserting columns 213 to insert into. Through this configuration, the fixing stability between the hard transparent shield 20 and the circuit board 11 can be further enhanced.

In practical applications, the waterproof transparent LED shield structure of the present invention can be used as the external waterproof and transparent structure of traffic sign boards, advertising objects, board-shaped decorative structures etc, so as to improve the waterproof and protection effect, and effectively extend the durability of the LED illumination component.

1. A waterproof transparent LED shield structure, comprising:
a singular LED component, including a circuit board and an LED lighting component connected on the front surface of the circuit board, and also multiple protruding electric pins connected on the back surface of the circuit board;
a hard transparent shield, attached to the front surface of the circuit board of the singular LED component, comprising a base board and an integral shield protruding from the center of the base board, where the base board is to cover the front side of the circuit board, and the base board is configured with a rim on the side edge to correspond to the side of the circuit board; the shield comprises a circular side wall and a top end, the shield is to enclose the LED lighting component, and the light beams from the LED lighting component can go through the shield;
a soft waterproof covering body, which is made of soft flexible material and directly formed to cover and attach to the outside of the singular LED component and the hard transparent shield;
the soft waterproof covering body comprises a seat part and a projecting part with a through hole on the end, configured on the center of one side of the seat part; the seat part is to cover the circuit board of the singular LED component, the connecting end of the electric pins and the base board and rim of the hard transparent shield, and the protruding end of the electric pins extends out of the seat part; the projecting part encloses the circular side wall of the shield of the hard transparent shield;
the top end of the shield extends out of the projecting part through the through hole on the end and be exposed.

2. The structure defined in claim 1, wherein the projecting part of the soft waterproof covering body, or the shield circular side wall of the hard transparent shield is further configured with a clip fixing pin; the shape of the clip fixing pin is in any form like spaced teeth or a ring-shaped flange; through the clip fixing pin, the product can be fixed onto the preset through hole of a board-shaped object; the clip fixing pin is configured as one stage or spaced multi-stages;
in configuration of spaced multi-stages, it can fit board-shaped objects of different thickness.

3. The structure defined in claim 1, wherein the front or back sides of the seat part of the soft waterproof covering body are adhered with double-sided adhesive, through which the product can be adhered onto the surface of a board-shaped object.

4. The structure defined in claim 1, wherein the LED lighting component configured on the front side of the circuit board of the singular LED component can be in any shape of a high cylinder-shaped, low cylinder-shaped, or flat rectangular granule; the LED lighting component can directly resists on the circuit board, or there can be a space with configuration of electric pins.

5. The structure defined in claim 1, wherein the rim configured on the side of the base board hard transparent shield is a ring-shaped frame or is in the shape of spaced multiple sheets;
the rim directly resists against the circuit board, or is spaced from the circuit board.

6. The structure defined in claim 1, wherein the electric pins configured on the back side of the circuit board of the singular LED component are folded like the letter “L”, or extend straightly to the outside of the circuit board.

7. The structure defined in claim 1, wherein the base board of the hard transparent shield is further configured with multiple inserting columns extending to the direction of the circuit board, and the circuit board is correspondingly configured with multiple fixing holes for the inserting columns to insert into.

8. The structure defined in claim 1, wherein the surface of the base board of the hard transparent shield is further configured with multiple flanges, and slots are formed between the flanges for the soft waterproof covering body to be inserted into, so as to enhance the fixing stability between the soft waterproof covering body and the hard transparent shield.
